(19) United States
(12) Patent Application Publication
(10) Pub. No.: US 2008/0094336 A1
(43) Pub. Date: Apr. 24, 2008

(54) INTEGRATED CIRCUIT MODULE AND METHOD FOR DATA TRANSMISSION

(75) Inventor: Sheng-kai Hsu, Hsin-Chu City (TW)

Correspondence Address: MADSON & AUSTIN, 15 WEST SOUTH TEMPLE, SUITE 900, SALT LAKE CITY, UT, 84101, US

(73) Assignee: AU Optronics Corp., Hsin-Chu (TW)

(21) Appl. No.: 11/775,534

(22) Filed: Jul. 10, 2007

(30) Foreign Application Priority Data
Oct. 20, 2006 (TW) 095138814

(51) Int. Cl. G09G 3/36; H03H 11/26

(52) U.S. Cl. 345/92; 327/271

(57) ABSTRACT

An integrated circuit (IC) module for data transmission and a method for the same are disclosed. According to the present invention, the connection is such that in the module a plurality of ICs is electrically connected to a plurality of transmission lines for transmitting data. The module further includes a stagger device for making data to be transmitted via the transmission lines asynchronously. The stagger device causes different delays for the respective transmission lines, so as to avoid the over transient current being generated in the module.

### TECHNICAL FIELD OF THE INVENTION

The present invention relates to data transmission, more particularly, to an integrated circuit (IC) module for data transmission and a method for the same.

### BACKGROUND OF THE INVENTION

As shown in FIG. 1, a general Thin Film Transistor Liquid Crystal Display (TFT-LCD) comprises a TFT-LCD panel 1, a plurality of source drivers 2, a plurality of gate drivers 3, a timing controller 4, a gray scale reference circuit 5, and a DC/DC converter 6. The TFT-LCD panel 1 has plural pixels arranged in a matrix. The gate drivers 3 are used to control on and off states of the pixels of each row. The source drivers 2 are used to provide driving voltages to pixels of the respective columns. The timing controller 4 is used to control the timing of the gate drivers 3 and the source drivers 2.

Also shown in the drawing, the source drivers 2 are electrically connected in a cascade manner, that is, ICs of the source drivers 2 are electrically connected stage by stage. Under the control of the timing controller, data is transmitted synchronously from the source driver IC of the previous stage to the source driver IC of the next stage via a plurality of transmission lines (only two lines are shown as representative lines in the drawing), so as to avoid the errors being generated in the data transmission. However, since the plurality of transmission lines transmit data at the same time, the data will be converted synchronously, and the total level of the transient currents may be too large, even exceeding the operating range of the driver IC, and a result of distortion may occur in the data.

Therefore, to resolve the above problem, a solution scheme is required.

### SUMMERY OF THE INVENTION

An objective of the present invention is to provide an integrated circuit (IC) module. According to the present invention, the module comprises a plurality of integrated circuits (ICs), a plurality of transmission lines connecting the ICs for transmitting data, and a stagger device for making data to be transmitted via the transmission lines asynchronously. The stagger device can be implemented by wires of different lengths, and the wires are respectively a part of the transmission lines, in essence. That is, the transmission lines with different lengths can be used to obtain different delays in practice. Alternatively, the stagger device can use delay units with fixed delay time to achieve different delays for the respective transmission lines. By making the transmission lines to transmit data at different times, over transient current can be avoided.

Another objective of the present invention is to provide a TFT-LCD with a source driver constructed in the aforementioned IC module.

A further objective of the present invention is to provide a data transmission method whereby a plurality of transmission lines connecting a plurality of ICs. The method according to the present invention provides different delays to a plurality of transmission lines, and data can be transmitted and received through the transmission lines. In addition, the different delays can be achieved by providing transmission lines with different lengths or by arranging delay units with fixed delay time. Accordingly, over transient current being generated can be avoided in the module.

### BRIEF DESCRIPTION OF THE DRAWINGS

FIG. 1 generally shows a module of TFT-LCD;

FIG. 2 generally shows an integrated circuit module for data transmission according to one embodiment of the present invention;

FIG. 3 generally shows another integrated circuit module for data transmission according to another embodiment of the present invention;

FIG. 4A shows current waveforms of respective transmission lines without a stagger scheme; and FIG. 4B shows current waveforms of respective transmission lines with a stagger scheme;

FIG. 5A shows schematically the current and the voltage without a stagger scheme; and FIG. 5B shows schematically the current and the voltage with a stagger scheme;

FIG. 6 generally shows another integrated circuit module for data transmission;

FIG. 7 shows an embodiment of the integrated circuit module for data transmission according to the present invention, and the stagger device is implemented by delay units;

FIG. 8 shows another embodiment of the integrated circuit module for dada transmission according to the present invention, and the stagger device and the reversion device are both implemented by delay units;

FIG. 9 generally shows a timing controller of the TFT-LCD electrically connected with a plurality of source drivers in a point-to-point manner;

FIG. 10 shows schematically an embodiment of the delay units according to the present invention;

FIG. 11 shows schematically another embodiment of the delay units according to the present invention; and

FIG. 12 shows schematically the delay unit converted to current interface according to the present invention.

### DETAILED DESCRIPTION OF THE INVENTION

The present invention will be described further in detail in conjunction with the accompanying drawings, wherein the same reference numbers denote the same components.

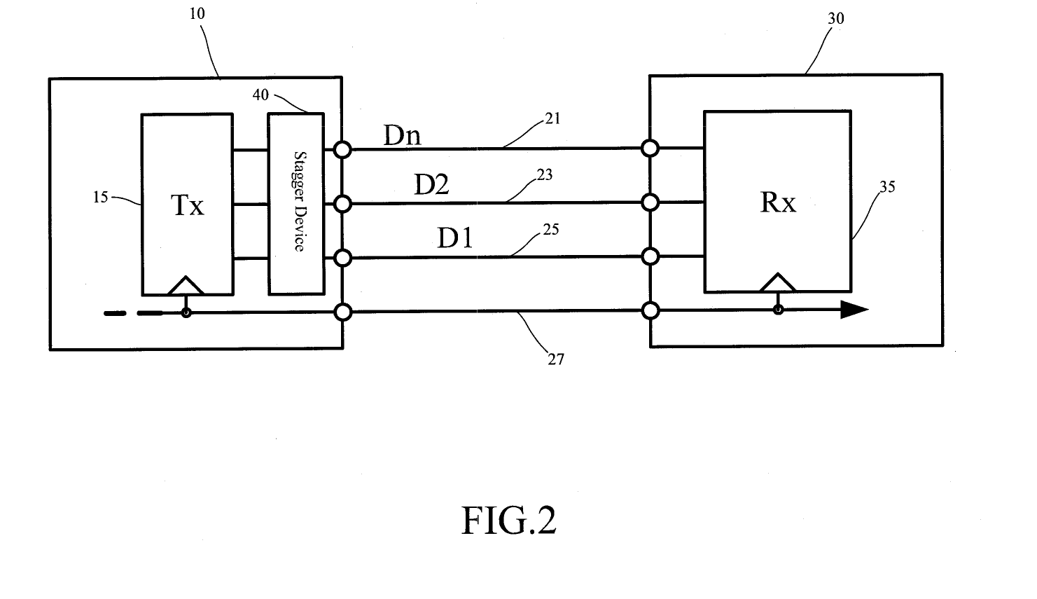

FIG. 2 generally shows an example of an IC module according to one embodiment of the present invention. Using a source transistor of TFT-LCD as an example, a reference number 10 indicates a previous driver IC stage including a transmission device 15. A reference number 30 indicates a next driver IC stage including a receiving device 35. It is noted that, although a source driver of the TFT-LCD is described as an example here, the technology should not be limited, and any IC for data transmission is adaptive. Data is transmitted from the previous IC stage 10 to the next IC stage 30 via a plurality of transmission lines 21, 23, and 25. In the embodiment, the transmission device 15 of the previous stage and the receiving device of the next stage 35 are synchronized based on a clock transmitted by a clock transmission line 27, so as to avoid the error being generated in data transmission. However, as aforementioned, if data is transmitted via the transmission lines 21, 23, and 25 synchronously, the data will be converted at the same time, and the transient current will be very large. To resolve the foregoing problem, the present invention provides a stagger device 40 at the transmission end. In the embodiment, the stagger device 40 is provided in the previous IC stage 15. The stagger device 40 provides different delays D1, D2, Dn for the transmission lines 21, 23, 25, to avoid the over transient current being generated in the module. Comparing to the transmission pulse period, the delayed time is very short, errors will not be generated in data transmission due to the delays. For example, if the frequency of data transmission is 80 MHz, then a pulse period is 12.5 ns. In comparison, only 1.5 ns delay is needed to stagger the transmission of the lines.

It is particularly advantageous for the module with longer transmission lines between the ICs to transmit data asynchronously via transmission lines with different delays.

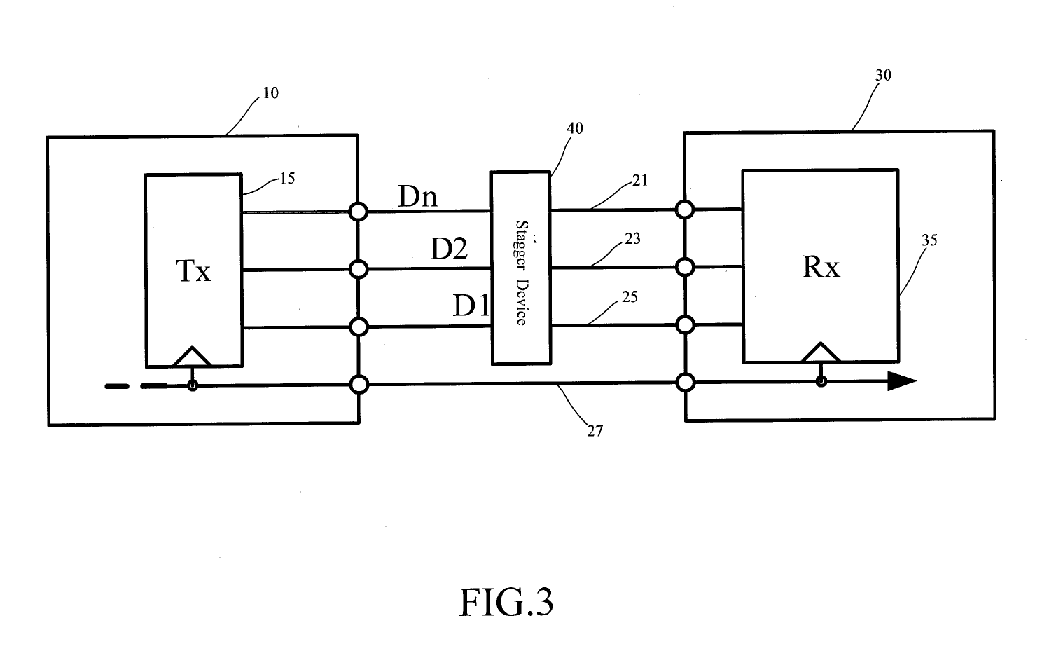

Although in the above embodiment, the stagger device is provided inside the previous IC stage, it can also be provided outside the IC, as shown in FIG. 3.

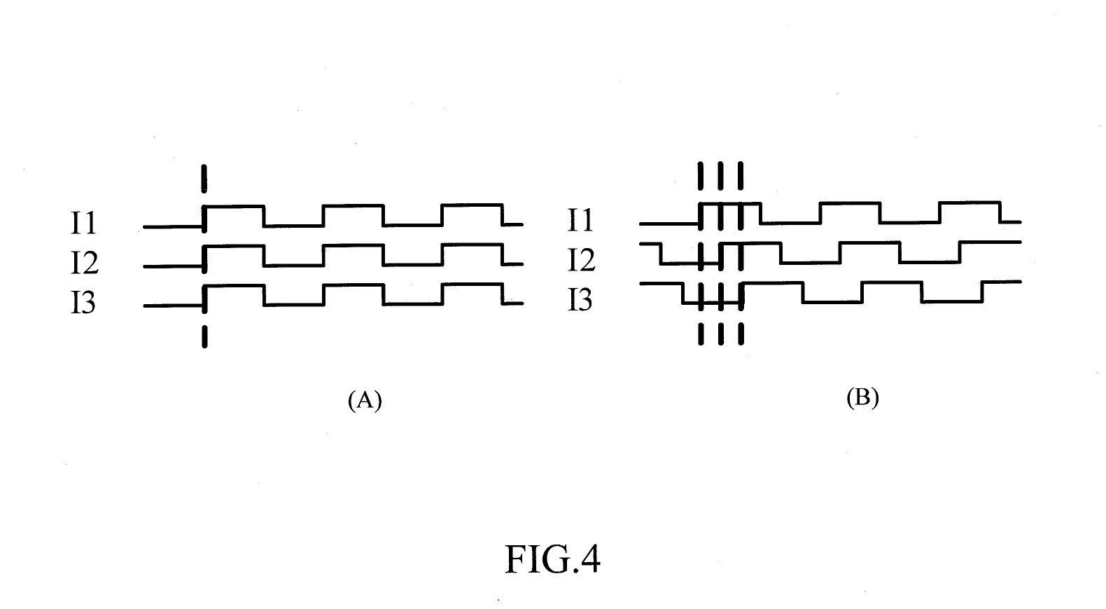

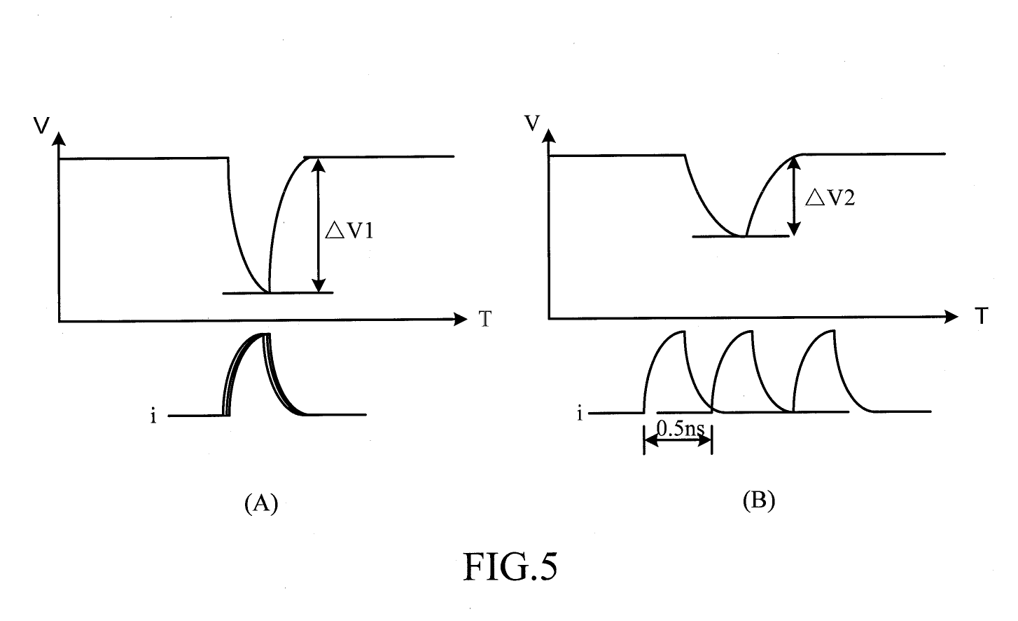

Referring to FIG. 4 in conjunction with FIG. 5. FIG. 4A shows current waveforms of the transmission lines not staggered. As shown, currents I1, I2 and I3 of the three transmission lines are generated synchronously. FIG. 4B shows current waveforms of the transmission lines staggered from each other, and the rising edges of currents I1, I2, I3 are slightly staggered from each other. FIG. 5A shows schematically the current and the voltage not staggered. FIG. 5B shows schematically the current and the voltage staggered from each other. As aforementioned, when data is transmitted via a plurality of transmission lines synchronously, the data is converted synchronously in the transmission lines and a plurality of transient currents is generated, therefore leads to an over-large transient voltage, labeled as Δ V1 in FIG. 5A. This may exceed the voltage operating range of the IC, and a distortion may be resulted accordingly. Whereas, when the transient currents are staggered by providing different delays, for example, the respective delays are staggered with each other by 0.5 ns, and then the voltage waveform can be smoother, labeled as Δ V2 in FIG. 5B, so the above problem can be avoided.

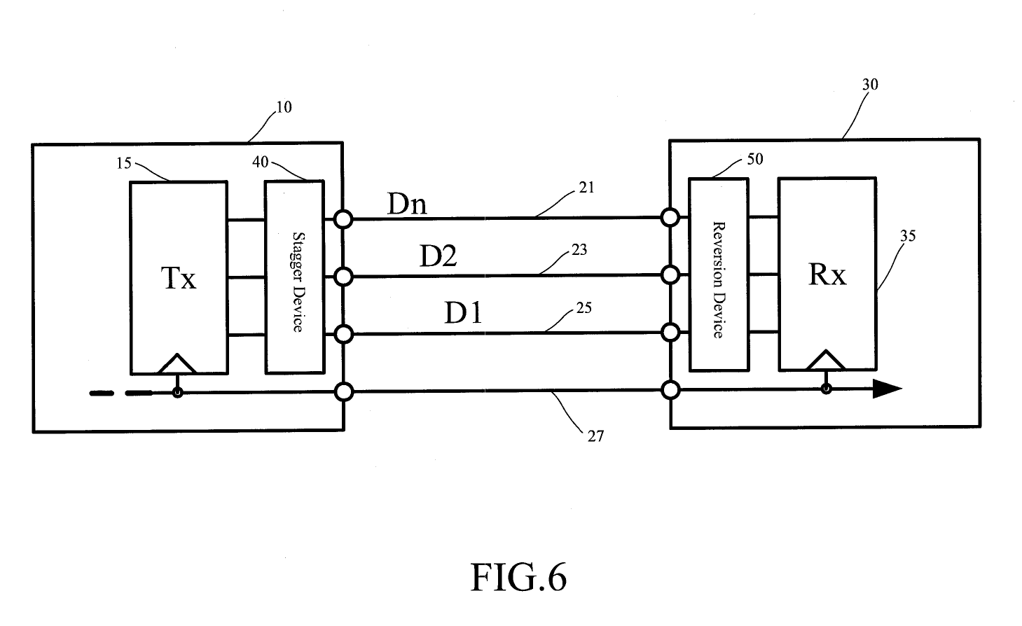

For the IC at the receiving end, if the tolerance for the asynchronous data transmission is large enough, it only needs to provide the stagger device 40 at the transmission end. However, for the IC with higher accuracy requirement, additional arrangement is needed. As shown in FIG. 6, in the present embodiment, the module is almost the same as the aforementioned embodiment, so descriptions of the same parts will be omitted. The difference lies in that a reversion device 50 is added in this present embodiment. In this embodiment, the reversion device 50 is provided inside the IC of the receiving end. The data staggered by the different delays of the stagger device 40 can be synchronized at the receiving end by the reversion device 50. Similarly, the reversion device 50 can also be provided outside the IC at the receiving end.

Implementations of the stagger device and the reversion device will be described in details in the following descriptions.

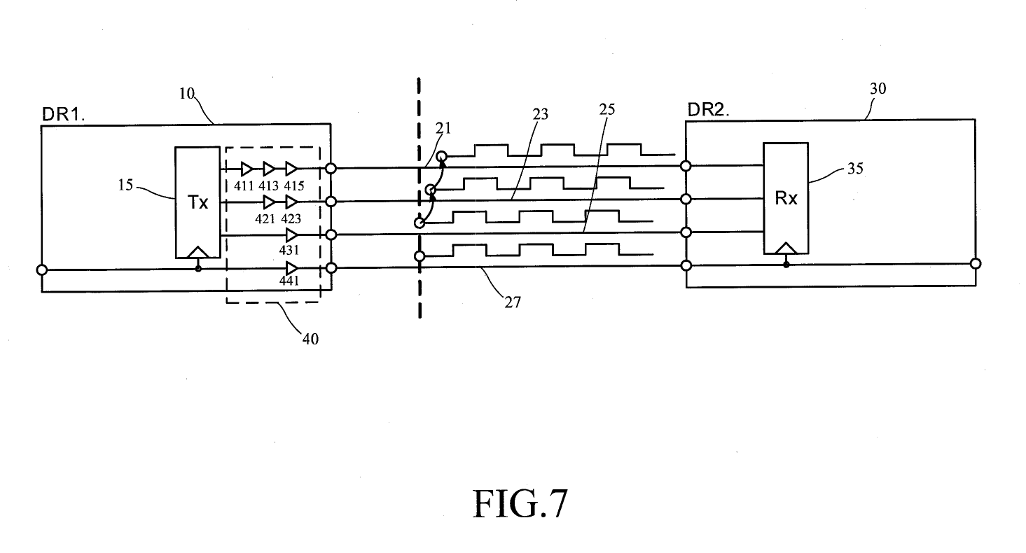

FIG. 7 shows an example for implementing the stagger device 40. As shown, different delays are obtained by using a plurality of delay units in the stagger device 40. In the present invention, the delay units are set to have the same delay value of 2 ns. As can be seen in FIG. 7, for the first transmission line 21, three delay units 411, 413, and 415 are used, that is, the total delay is 6 ns. For the second transmission line 23, the two delay units 421 and 423 are used, and the total delay is 4 ns. And for the third transmission line 25 as well as the clock transmission line 27, a delay unit 431 and a delay unit 441 are used respectively, each delays 2 ns. By this means, the data can be transmitted asynchronously, and the over transient current can be avoided accordingly.

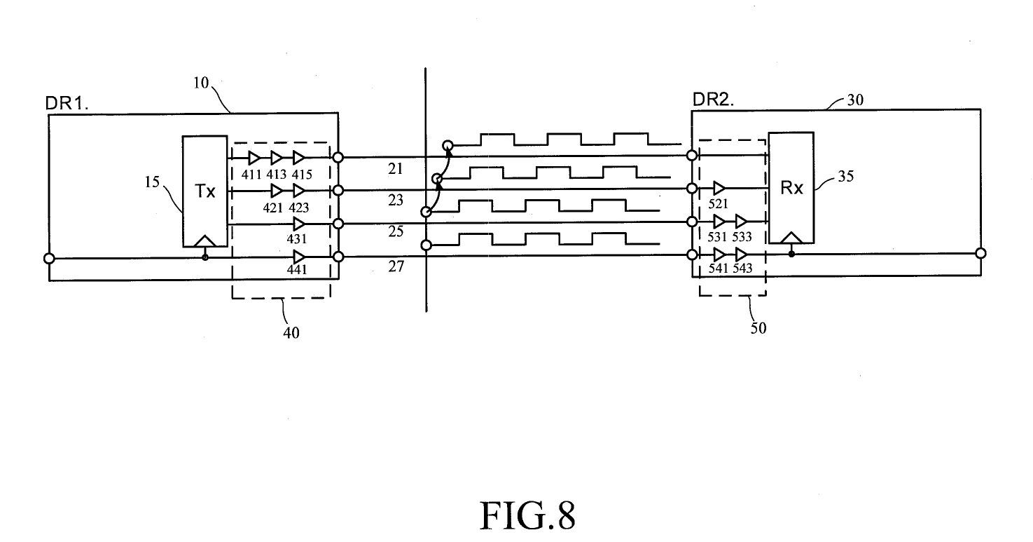

The reversion device 50 can be implemented in the same way. Referring to FIG. 8, where the same parts are shown as in FIG. 7, therefore no further description will be provided. As shown in FIG. 8, the reversion device 50 comprises a plurality of delay units. In the present embodiment, the delay provided by each of the delay units is also 2 ns. Providing a number of delay units to the reversion device 50 for the transmission lines 21, 23, and 25, to attach with different delays provided by the stagger device 40, the same delay time can be achieved at the receiving end. For example, for the first transmission line 21 as shown, the reversion device 50 provides no delay unit, so the total delay time is 6 ns at the receiving end. For the second transmission line 23 as shown, the reversion device 50 provides one delay unit 521, therefore achieving a total delay time of 6 ns, that is 4 ns+2 ns=6 ns, at the receiving end. And for the third transmission line 25 as well as the clock transmission line 27 as shown, the reversion device 50 provides to each with two delay units 531, 533, and 541, 543, respectively, so the total delay time at each receiving end is also 6 ns, that is 2 ns+4 ns=6 ns. It can be known that, by providing a number of delay units to achieve a same total delay time, so that the data can be received synchronously at the receiving end.

It should be noted that it is not necessary to have delay units with the same delay time in order to achieve the same total delay time at the receiving end, delay units with different delays can also be used. The required delay time can be achieved by properly arranging the delay units with different delay times.

In addition to utilizing the delay units, the delay effect can be achieved by using wires of certain lengths. That is, wires of different lengths can also be used to achieve different delays. In implementation, the objective of the present invention can be obtained by utilizing the transmission lines of wires of different lengths connecting the previous IC stage and the next IC stage.

When the different delays are obtained by using wires with different lengths in stagger device 40, and each wire is a part of the transmission line in essence, the reversion device 50 can still adjust the total delay time at the receiving end by using the delay units.

Although in the above descriptions, the cascade module is used as an example describing the technical features of the present invention, an IC module with a point-to-point connection can be used also.

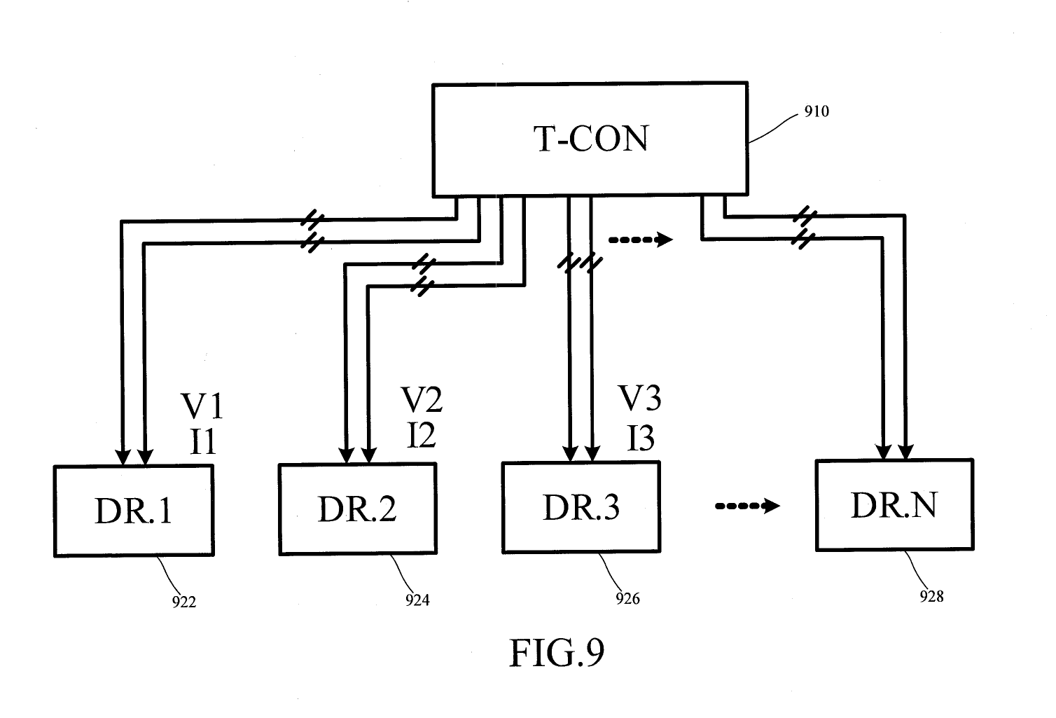

FIG. 9 shows a timing controller in a TFT-LCD electrically connected with a plurality of source drivers 922, 924, 926, and 928 in the point-to-point manner. In the module, the timing controller 910 is respectively electrically connected to the source drivers 922, 924, 926, and 928 by a plurality of transmission lines. Similarly, in order to avoid an over transient current being generated at the same time, a stagger device is provided to the transmission lines connecting the timing controller 910 and each source driver. The stagger device can also be implemented by wires of different lengths.

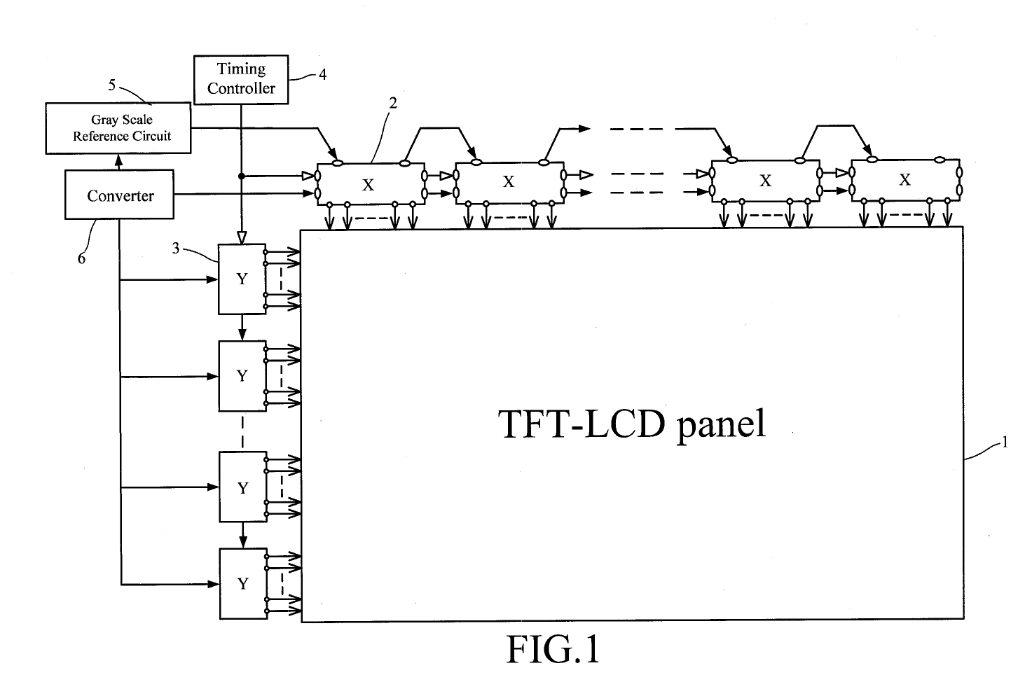

The scheme using different delays to avoid the over transient current in accordance with the present invention not only can be applied to the plurality of transmission lines between two ICs, but also can be used in the transmission lines between multiple ICs. As shown in FIG. 1 and FIG. 9, the source drivers are electrically connected with the timing controller in a cascade manner or in a point-to-point manner. As shown in FIG. 1, the ICs are electrically connected with each other by a plurality of transmission lines. Further, since there are multiple ICs, the number of transmission lines is increased in proportion to the number of the ICs. In FIG. 9, the number of the transmission lines, which are used to connect each IC with the timing controller, increases in proportion according to the number of ICs. According to the present invention, different delays are used to avoid the over transient current being generated by transmitting the data asynchronously not only can be used in the transmission lines between two ICs, but also can be used in the transmission lines between the multiple ICs. That is, in the whole module scheme, delay difference can make the number of the transmission lines transmit data at the same time smaller than a predetermined number at each time point. Also, the predetermined number can be determined according to the largest transient current tolerable by the whole module. As aforementioned, in implementation, different delays can be achieved by using transmission lines of different lengths. Different delays can also be achieved by adjusting a synchronization circuit of the module, that is, the stagger device can be implemented by the synchronization circuit. Furthermore, various delay units can also be used.

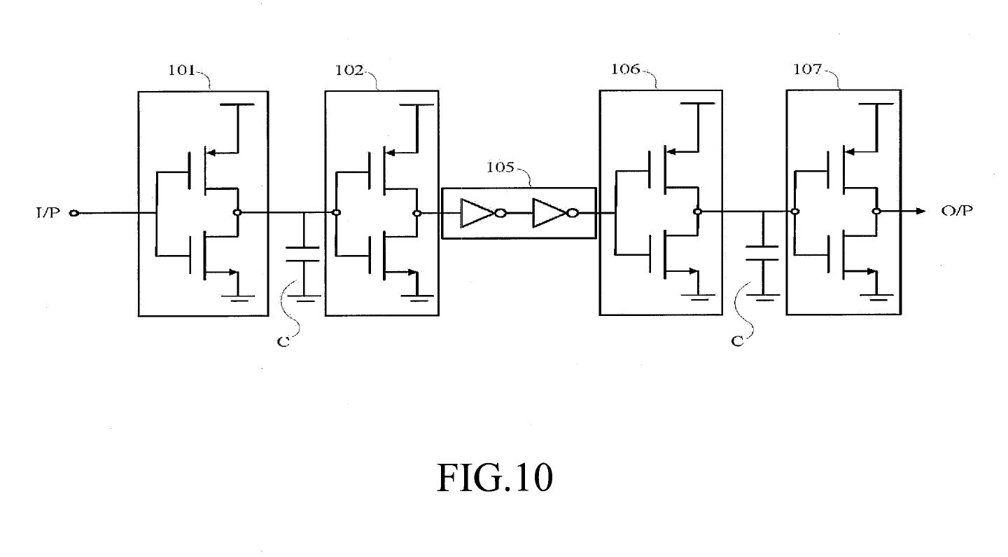

FIG. 10 shows an application embodiment in which delay units are implemented by transistors. Each of the delay units 101, 102, 106, and 107 includes a transistor pair with the gates connecting to one another, and the required delay time can be achieved by controlling the size of the transistors. When multiple delay units like such are electrically connected in series, a capacitor C is provided between every two delay units to separate the two delay units. In addition, when a large number of delay units are electrically connected in series, a distortion may occur in the signal. The present invention provides a retrieving unit 105 to adjust the distortion signals back to the original state. In this example, the retrieving unit 105 comprises two inverters electrically connected in series.

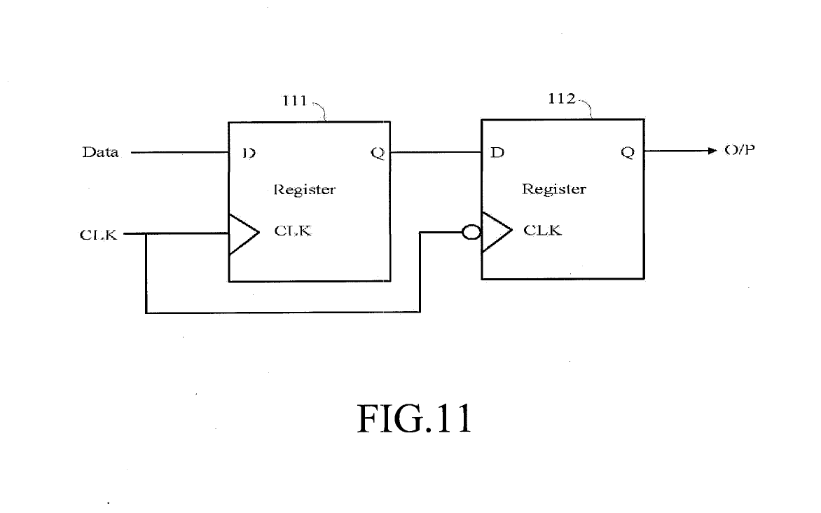

Another embodiment of the delay unit is shown in FIG. 11. In the embodiment, registers 111 and 112 are used as delay units, the required delay time can be obtained by controlling a clock signal CLK fed to the registers 111 and 112.

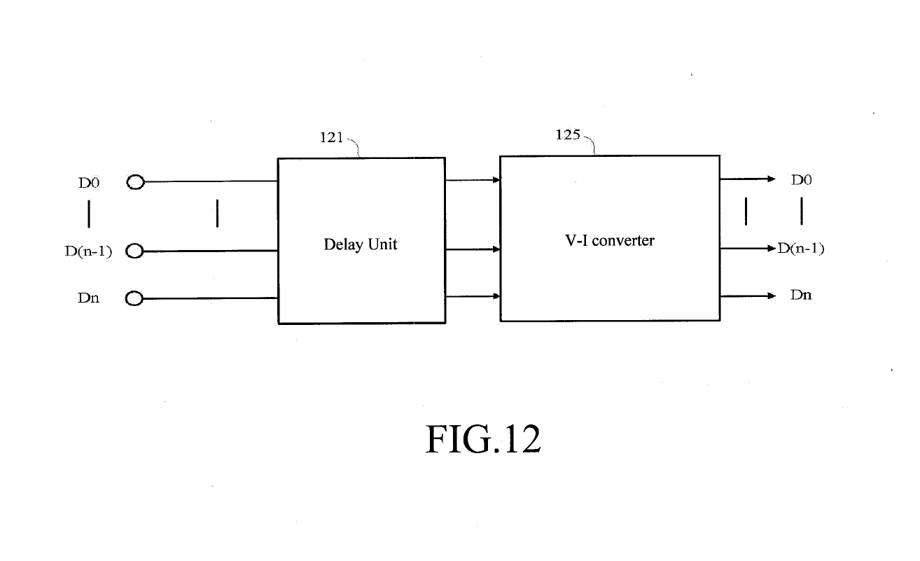

In general, the delay unit is implemented by a voltage interface. However, if a current interface is required, it is shown in FIG. 12. The present invention provides a voltage-current (V-I) converter 125 to connect to the voltage-interface delay unit 121 implemented by circuitry such as a transistor pair, to convert the delay into current interface.

While the preferred embodiment of the present invention has been illustrated and described in details, various modifications and alterations can be made by persons skilled in this art. The embodiment of the present invention is therefore described in an illustrative but not in a restrictive sense. It is intended that the present invention should not be limited to the particular forms as illustrated, and that all modifications and alterations which maintain the spirit and realm of the present invention are within the scope as defined in the appended claims.

What is claimed is:

1. An integrated circuit (IC) module comprising:
a plurality of integrated circuits (ICs);
a plurality of transmission lines connecting the integrated circuits for transmitting data; and
a stagger device for making data to be transmitted via the transmission lines asynchronously.

2. The integrated circuit module according to claim 1, wherein the stagger device comprises a plurality of delay units electrically connected to the transmission lines.

3. The integrated circuit module according to claim 2, wherein each of the delay units includes a transistor pair or a register.

4. The integrated circuit module according to claim 2 further comprising a voltage-current converter coupled to each delay unit to convert the voltage output of the delay unit into current.

5. The integrated circuit module according to claim 1, wherein the stagger device is implemented by wires of different lengths.

6. The integrated circuit module according to claim 5, wherein each wire is substantially a part of each transmission line.

7. The integrated circuit module according to claim 1, wherein the ICs are electrically connected by the transmission lines in one of a cascade manner and a point-to-point manner.

8. The integrated circuit module according to claim 1, wherein the data is transmitted from an IC at a transmitting end to an IC at a receiving end, and the integrated circuit module further includes a reversion device for making the data transmitted via the transmission lines with different delays to be synchronously received by the IC at the receiving end.

9. The integrated circuit module according to claim 8, wherein the reversion device includes a plurality of delay units connecting to the transmission lines for making the data transmitted via the transmission lines with different delays to be received by the IC at the receiving end synchronously.

10. The integrated circuit module according to claim 9, wherein each of the delay units includes a transistor pair or a register.

11. The integrated circuit module according to claim 9 further comprising a voltage-current converter coupled to each delay unit to convert the voltage output of the delay units into current.

12. A thin film transistor liquid crystal display comprising:
a thin film transistor liquid crystal display panel having plural pixels arranged in a matrix;
a plurality of gate drivers for controlling on and off states of the pixels of each row of the matrix;
a plurality of source drivers for providing driving voltages to pixels of the respective columns of the matrix;
a timing controller for controlling the timing of the gate drivers and the source drivers, the timing controller being electrically connected with the source drivers by a plurality of transmission lines; and
a stagger device for making data to be transmitted via the plurality of transmission lines between the source drivers asynchronously.

13. The thin film transistor liquid crystal display according to claim 12, wherein the stagger device includes a plurality of delay units electrically connected to the plurality of transmission lines.

14. The thin film transistor liquid crystal display according to claim 13, wherein each of the delay units includes a transistor pair or a register.

15. The thin film transistor liquid crystal display according to claim 13 further comprising a voltage-current converter coupled to each delay unit to convert the voltage output of the delay unit into current.

16. The thin film transistor liquid crystal display according to claim 12, wherein the stagger device is implemented by wires of different lengths.

17. The thin film transistor liquid crystal display according to claim 16, wherein each wire is substantially a part of each transmission line.

18. The thin film transistor liquid crystal display according to claim 12, wherein the source drivers are electrically connected to the timing controller with the transmission lines in one of a cascade manner and a point-to-point manner.

19. The thin film transistor liquid crystal display according to claim 12 further comprising a reversion device for making the data transmitted via the transmission lines with different delays to be synchronously received by the IC at the receiving end.

20. The thin film transistor liquid crystal display according to claim 19, wherein the reversion device includes a plurality of delay units electrically connected to the transmission lines to make the data transmitted with different delays via the transmission lines arrive at the receiving end synchronously.

21. The thin film transistor liquid crystal display according to claim 20, wherein each of the delay unit includes a transistor pair and a register.

22. The thin film transistor liquid crystal display according to claim 20, further includes a voltage-current converter electrically coupled to each delay unit to convert the voltage output of the delay units into current.

23. A method for data transmission comprising:
providing different delays for a plurality of transmission lines;
transmitting data through the plurality of transmission lines; and
receiving the data transmitted by the transmission lines.

24. The method according to claim 23, wherein the different delays provided by the plurality of delay units whereby the delay units are electrically connected to the transmission lines.

25. The method according to claim 23, wherein the different delays are provided by wires of different lengths.

26. The method according to claim 25, wherein the wires are respectively a part of the transmission lines in essence.

27. The method according to claim 23, wherein the ICs are electrically connected with the transmission lines in one of a cascade manner and a point-to-point manner.

28. The method according to claim 23, further comprising a reverting step for making the data transmitted with different delays via the transmission lines arrive at the receiving end synchronously.

29. The method according to claim 28, wherein the reverting step comprises connecting a plurality of delay units to the transmission lines to make the data transmitted with different delays via the transmission lines arrive at the receiving end synchronously.
